(19) United States
(12) Patent Application Publication
(10) Pub. No.: US 2015/0255289 A1
(43) Pub. Date: Sep. 10, 2015

(54) METHOD FOR MANUFACTURING A SEMICONDUCTOR STRUCTURE

(71) Applicant: INSTITUTE OF MICROELECTRONICS, CHINESE ACADEMY OF SCIENCES, Beijing (CN)

(72) Inventors: Haizhou Yin, Poughkeepsie, NY (US); Huilong Zhu, Poughkeepsie, NY (US)

(21) Appl. No.: 14/430,569

(22) PCT Filed: Oct. 23, 2012
(86) PCT No.: PCT/CN2012/083338

§ 371 Date: Mar. 24, 2015

(30) Foreign Application Priority Data
Sep. 25, 2012 (CN) 201210362169.2

(51) Int. Cl. H01L 21/265; H01L 21/324; H01L 29/66

(52) U.S. Cl. CPC H01L 21/26513; H01L 29/66742; H01L 21/324

(57) ABSTRACT

A method for manufacturing a semiconductor structure is disclosed. The method comprises: a) providing an SOI substrate, and forming a gate stack on the SOI substrate; b) conducting amorphous implantation to source/drain regions, wherein process temperature of the amorphous implantation to the source region is higher than process temperature of the amorphous implantation to the drain region; c)performing the source/drain region doping; d) annealing to activate the impurities and recrystallize the amorphous region of the source/drain regions. In step b), the process temperature is higher than 50 in the amorphous implantation to the source region whereas the process temperature is lower than −30 in the amorphous implantation to the drain region. The present invention provides a method to generate defects under the source region. The defects can serve as discharge channels for the charges accumulated in the bulk region to reduce the impact of the floating bulk effect and to improve the reliability of the device.

### CROSS-REFERENCE TO RELATED APPLICATION

This application claims priority to the Chinese Patent Application No. 201210362169.2, filed on Sep. 25, 2012, entitled “Method for Manufacturing a Semiconductor Structure”, which is incorporated herein by reference in its entirety.

### TECHNICAL FIELD

The present disclosure relates to the field of semiconductor manufacturing, and in particular, to a method for manufacturing a semiconductor structure.

### BACKGROUND OF THE INVENTION

In order to improve the performance and integration of integrated circuit chips, device feature sizes continue to shrink in accordance with Moore's Law and have currently reached nano scale. With the reduction of device volumes, power consumption and leakage current become the most concerned issue. CMOS devices made with SOI (Silicon on Insulator) technology has many advantages such as high speed, low power consumption, high degree of integration, radiation resistance and no self-locking effect etc., and has become the preferred structure for deep sub-micron and nanoscale MOS devices.

Depending on whether the bulk region is depleted, SOI devices can be classified into two categories: partially depleted devices and fully depleted devices. Generally, fully depleted SOI devices have thin top silicon film, and threshold voltage is difficult to control for these devices. Therefore, partially depleted SOI devices are still commonly used and cost-effective solutions. For partially depleted SOI devices, as the bulk region is not completely depleted, the bulk region is still in suspended state, and the charge generated by impact and ionization cannot be quickly removed, leading to the emergence of floating bulk effect. For SOI NMOS devices, electron-hole pairs are generated by the impact ionization of channel electrons at the drain, and then the holes flow to the bulk region, and accumulate in the bulk region, raising the potential of the bulk region, leading to the reduction of the NMOS threshold voltage and the increase in leakage current, hence causing the warping of the device output characteristic curve, which is not beneficial to the performance and reliability of the device and circuit. For PMOS devices, hole ionization rate is lower, and the electron-hole pairs generated by impact ionization are far less than that of NMOS devices, so the impact of floating bulk effect is weaker.

To resolve the floating bulk effects, bulk contact method is usually adopted, to make electrical leads in the bulk region that are connected to a constant potential (source or ground), providing a discharge channel for the charge accumulated in the bulk region, and reducing the potential of the bulk region. However, this generally complicates manufacturing processes, increases device manufacturing costs, and lowers some electrical performances while increasing device area.

### SUMMARY OF THE DISCLOSURE

The purpose of the present disclosure is to resolve the above mentioned technical defects at least, by providing a method to reduce the floating bulk effects of SOI devices and to improve the performance and reliability of semiconductor devices.

In order to achieve the above objective, the present disclosure provides a method for manufacturing a semiconductor structure, which comprises the following steps:

a) providing an SOI substrate, and forming a gate stack on the SOI substrate;

b) conducting amorphous implantation to source/drain regions, wherein process temperature of the amorphous implantation to the source region is higher than process temperature of the amorphous implantation to the drain region;

c) performing source/drain regions doping;

d) annealing to activate the impurities and recrystallize the amorphous region of the source/drain region.

In one embodiment of the present disclosure, in step b), the process temperature is higher than 50 in the amorphous implantation to the source region, whereas the process temperature is lower than −30 in the amorphous implantation to the drain region.

Preferably, the ion implanted into the source region and the drain region by amorphous implantation is silicon or germanium. The process temperature is lower than −30 and the implantation depth is 50˜70 nm.

According to the manufacturing method provided in the present disclosure, after the completion of annealing, the amorphous region of the drain region recrystallizes with almost no defects remaining, whereas the source region amorphization takes place under a relatively high temperature with many defects remaining after annealing. These defects can serve as discharge channels between the source region and the bulk region to reduce the impact of the floating bulk effect and to improve the reliability of the device. Meanwhile, since process steps are only added to the manufacturing of the source/drain regions, the standard semiconductor manufacturing processes will not be affected, the electrical leads in the bulk region will not be needed, and the device area will not be increased.

### BRIEF DESCRIPTION OF THE DRAWINGS

The above mentioned and/or other additional features and advantages of the present disclosure will become more apparent and easy to understand by the detailed description of embodiments with reference to the attached drawings, wherein:

FIG. 1 is a schematic flowchart of one embodiment applying the method for manufacturing a semiconductor structure according to the present disclosure;

FIGS. 2 to 7 are schematic cross-sectional views or top views of the semiconductor structure in various stages of the manufacturing process following the method illustrated in FIG. 1.

### DETAILED DESCRIPTION

The embodiment of the present disclosure will be described in detail. The example of the embodiment is presented in the attached drawings, the same or similar reference numerals refer to the same or similar elements or the elements with the same or similar functions throughout the disclosure. The embodiment described below by reference to the drawings is exemplary, and is only used for explaining the present disclosure, and cannot be considered as limiting the present disclosure. The following disclosure provides many different embodiments or examples to achieve different structures of the present invention. In order to simplify the disclosure of the present invention, the components and settings of a set of specific examples will be described herein. Certainly, they are only examples, and are not to limit the present invention. In addition, the present disclosure may repeat the reference numerals and/or letters in different examples. This repetition is only for simplification and clarity purposes, rather than indicating any relationship between various embodiments and/or settings discussed. In addition, the present disclosure provides various examples of specific processes and materials, but technical people skilled in the art may appreciate the application and applicability of other processes and/or materials. Further, the structure described below of a first feature “on” a second feature may include an embodiment with the first and second features forming direct contact, and may also include an embodiment with additional features formed between the first and second feature, in which case the first and second features may not be in direct contact.

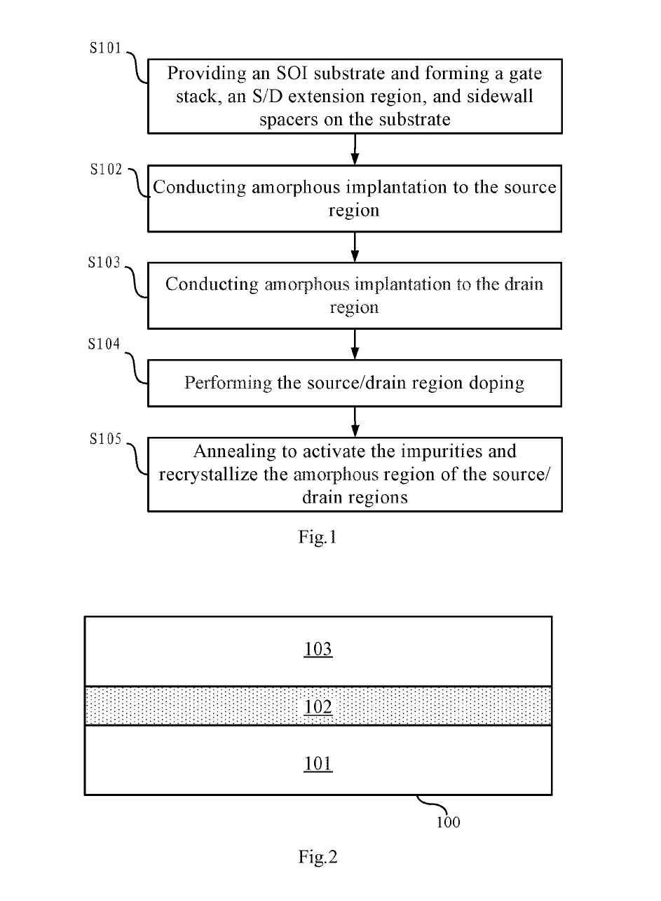

FIG. 1 is a schematic flowchart of the method for manufacturing a semiconductor structure according to the present disclosure. As one embodiment of the present disclosure, FIGS. 2 to 7 are schematic cross-sectional views of a semiconductor structure in various stages of the manufacturing process following the flowchart illustrated in FIG. 1. The method of forming a semiconductor structure shown in FIG. 1 will be described in detail with reference to FIGS. 2 to 7. It should be noted that the attached drawings of the embodiment are for illustration purpose only, and are not necessarily drawn in proportion.

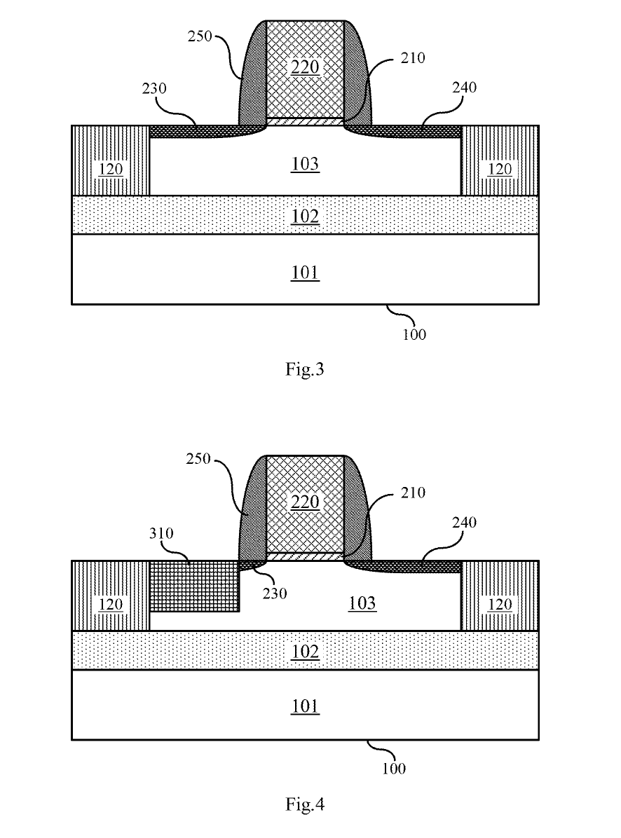

Referring to FIGS. 2 to 3, in step S101, an SOI substrate 100 is provided and a gate stack, a source/drain extension regions 230 and 240, and sidewall spacers 250 are sequentially formed on the SOI substrate 100.

As shown in FIG. 2, the SOI substrate 100 comprises a base layer 101, an insulation layer 102 located on the base layer 101, and a device layer 103 located on the insulation layer 102.

In the present embodiment, the base layer 101 is monocrystalline silicon. In other embodiments, the base layer 101 may comprise other basic semiconductors such as germanium, or other compound semiconductors, for example, silicon carbide, gallium arsenide, indium arsenide, or indium phosphide. Typically, the base layer 101 may have a thickness of about, but not limited to, several hundred micrometers, such as a thickness range of 0.2 mm˜1 mm. The insulation layer 102 can be SiO₂, silicon nitride, Al₂O₃ or any other suitable, insulating materials. Typically, the insulation layer 102 has a thickness range of 10 nm˜300 nm.

The device layer 103 can be any one of the semiconductors that the base layer 101 comprises. In the present embodiment, the device layer 103 is monocrystalline silicon. In other embodiments, the device layer 103 may comprise other basic semiconductors or compound semiconductors. Typically, the device layer 103 has a thickness range of 10 nm˜100 nm.

Subsequently, as shown in FIG. 3, the gate stack, the source/drain extension regions 230 and 240, and the sidewall spacers 250 are formed on the SOI substrate 100.

The gate stack comprises a gate dielectric layer 210 and a gate 220. Optionally, the gate stack may also comprise a cover layer (not shown in the figure) covering the gate, for example, formed by deposition of silicon nitride, silicon oxide, silicon oxynitride, silicon carbide, and combinations thereof, for protection of the top area of the gate 220, preventing it from being damaged in subsequent processes, The gate dielectric layer 210 is located above the surface device layer 103 on the SOI substrate 100, and may be high K dielectric, for example, HfO₂, HfSiO, HfSiON, HfTaO, HfTiO, HfZrO, Al₂O₃, La₂O₃, ZrO₂, LaAlO or the combinations thereof. In another embodiment, the gate dielectric layer 210 may also be a thermal oxide layer comprising silicon oxide or silicon ox nitride. The gate dielectric layer 210 may have a thickness of 1 nm˜10 nm, such as 5 nm or 8 nm. Then the gate 220 is formed on the gate dielectric layer 210. The gate 220 may be heavily doped polysilicon formed by deposition, or heavily doped polysilicon, Ti, Co, Ni, Al, W or an alloy thereof formed on a work function metal layer (for NMOS, such as TaC, TiN, TaTbN, TaErN, TaYbN, TaSiN, HfSiN, MoSiN, RuTaₓ, NiTaₓ etc.; and for PMOS, such as MoNₓ, TiSiN, TiCN, TaAlC, TiAlN, TaN, PtSiₓ, Ni₃Si, Pt, Ru, Ir, Mo, HfRu, RuOₓ), which is formed first and has a thickness of 1 nm-20 nm, such as 3 nm, 5 nm, 8 nm, 10 nm, 12 nm, or 15 nm.

In some other embodiments of the present disclosure, gate last process may also be adopted, wherein the gate stack comprises a gate 220 (in this case, a dummy gate) and a gate dielectric layer 210 bearing the gate. The gate 220 (in this case, a dummy gate) is formed on the gate dielectric layer 210 by deposition of, for example, polycrystalline silicon, polycrystalline SiGe, amorphous silicon, doped or non-doped silicon oxide and silicon nitride, silicon oxynitride, silicon carbide, or even metal, with a thickness of 10 nm˜80 nm. Optionally, a cover layer may also be formed on the gate 220 (in this case, a dummy gate) by deposition of, for example, silicon nitride, silicon oxide, silicon oxynitride, carbide, and combinations thereof, for protection of the top area of the dummy gate 220, preventing it from reacting with the deposited metal layer in the subsequent process for forming the contact layer. In another embodiment employing the gate last process, the gate stack may have no such a gate dielectric layer 210. Instead, the gate dielectric layer 210 is formed in subsequent process after removal of the dummy gate and before filling of the work function metal layer.

After forming the gate stack, the source/drain extension regions 230 and 240 are formed on both sides of the gate stack by using the gate stack as a mask to implant P-type or N-type dopants to the device layer 103. For PMOS, the source extension region 230 and the drain extension region 240 are P-type doped; and for NMOS, the source extension region 230 and the drain extension region 240 are N-type doped.

Subsequently, sidewall spacers 250 are formed on the sidewall of the gate stack to isolate the gate stack. Sidewall spacers 250 may comprise silicon nitride, silicon oxide, silicon oxynitride, silicon carbide, or combinations thereof, and/or other suitable materials. Sidewall spacers 250 may have a multilayer structure, and may be formed by deposition-etching process, with a thickness range of 10 nm˜100 nm, such as 30 nm, 50 nm, or 80 nm.

Referring to FIG. 4, step S102 is executed. Amorphous implantation to the source region is performed. First, lithography is conducted with photoresist covering the drain region. Then amorphous implantation is conducted to the exposed source extension region 230 to form the source amorphous region 310 as shown in FIG. 4. The ion implanted is silicon or germanium. The process temperature is higher than the process temperature of the amorphous implantation to the drain region, for example, higher than 50° C. The implantation depth is controlled in the range of 50˜70 nm by adjusting parameters such as implantation dose, energy etc.

Referring to FIG. 5, step S103 is executed. Amorphous implantation to the drain region is performed. Lithography is conducted with photoresist covering the source region. Then amorphous implantation is conducted to the exposed drain extension region 240 to form the drain amorphous region 320 as shown in FIG. 5. The ion implanted is silicon or germanium. The process temperature is lower than the process temperature of the amorphous implantation to the source region, for example, lower than −30° C. Optionally, liquid nitrogen cooling may be chosen to control the process temperature. Low process temperature can reduce the area with possible implantation defects, therefore substantially reduce defects in the subsequent processes. The implantation depth is controlled in the range of 50˜70 nm, by adjusting parameters such as implantation dose, energy etc.

The above steps of performing amorphous implantation to the source region and the drain region can be altered in sequence, i.e., amorphous implantation to the drain region may be conducted first according to the above drain region implantation process with the source region covered, then amorphous implantation to the source region may be conducted secondly according to the above source region implantation process with the drain region covered.

The above steps of amorphous process may also be performed after formation of the gate stack and before the formation of source/drain extension regions 230, 240 and sidewall spacers 250.

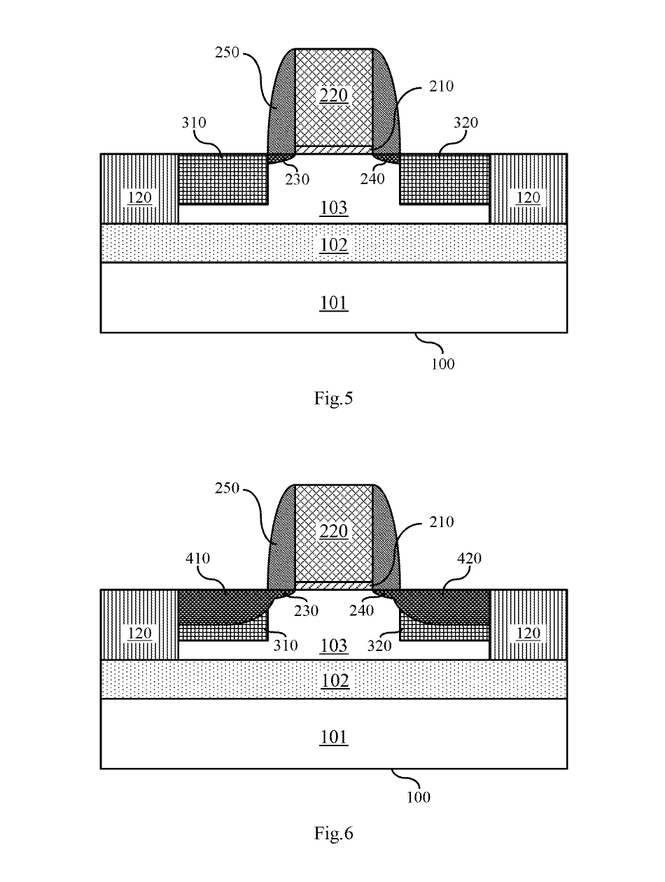

Referring to FIG. 6, step S104 is executed. Doping of the source region 410 and the drain region 420 is performed. Using the gate stack and sidewall spacers 250 as a mask, P-type or N-type dopants are implanted into the substrate to form the source region 410 and the drain region 420. For PMOS, the source region 410 and the drain region 420 are p-doped and the ion implanted is B or BF₂; and for NMOS, the source region 410 and the drain region 420 are n-doped and the ion implanted is P or As. Since amorphous implantation of source/drain region was conducted in steps S102 and S103, anomalous diffusion of the dopant ions such as boron can be effectively prevented in the doping process of the source/drain region.

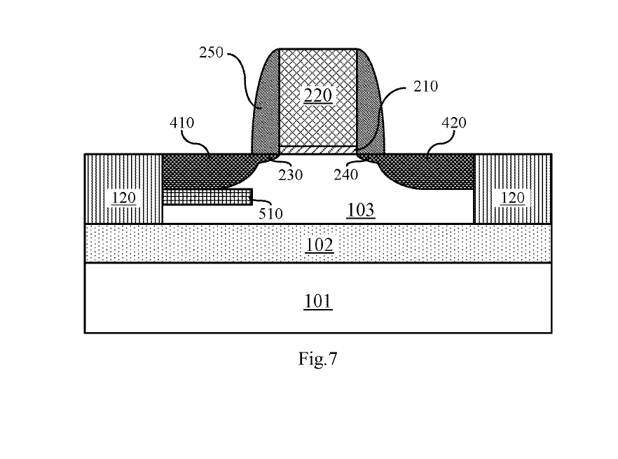

Next, step S105 is executed. Annealing is performed to activate the impurities and the amorphous region of the source/drain region is recrystallized. Methods including rapid thermal annealing, spike annealing, and other suitable methods can be used for the annealing. Annealing temperature is higher than 900° C. After annealing, the drain amorphous region 320 recrystallizes, generating very few defects, as few defects are generated in the amorphous implantation to the drain region due to lower process temperature. For the source region, the source amorphous region 310 recrystallizes after annealing. However, because the source region amorphization takes place under a relatively higher temperature, defects generated cannot be completely eliminated during the annealing process, leaving a number of defects remained in the source region and forming a defect region 510, as shown in FIG. 7. These defects can serve as discharge channels between the source region 410 and the bulk region of the device layer 103 to reduce the floating bulk effect of SW devices and to improve the reliability of the devices. Meanwhile, since process steps are only added to the manufacturing of the source/drain region, the standard semiconductor manufacturing processes will not be affected, the electrical leads in the bulk region will not be needed, and the device area will not be increased.

Subsequently, the manufacturing of the semiconductor structure is completed following the conventional semiconductor manufacturing process steps, e.g., formation of a metal suicide on the source/drain region; deposition of an interlayer dielectric layer to cover the source/drain region and the gate stack; etching of the interlayer dielectric layer to expose the source/drain region, formation of contact holes, filling of the contact holes with metal; and subsequent processes such as interconnection of multi-layer metal etc. Alternatively, in the replacement gate process, subsequent processes include removal of the dummy gate, formation a metal gate, etc.

While the exemplary embodiment and its advantages have been described in detail, it should be understood that without deviating from the spirit of the invention and the scope of protection defined in the appended claims, various changes, substitutions and modifications can be made to these embodiments. For other examples, people skilled in the art should easily understand that without deviating from the scope of protection of the present disclosure, the order of process steps may be changed.

Additionally, the scope of application of the present invention is not limited to the processes, organization, manufacturing, material composition, means, methods and steps described herein for the particular embodiments. From the disclosure of the present invention, people skilled in the art may easily understand, for the processes, organization, manufacturing, material composition, means, methods or steps that are currently existing or to be developed later, they can be used in accordance with the present invention, to execute virtually the same functions as the embodiments described in the present invention or to achieve virtually the same results. Accordingly, the appended claims of the present invention seek to include these processes, organization, manufacturing, material composition, means, methods or steps in the scope of protection.

1. A method for manufacturing a semiconductor structure, comprising:
a) providing an SOI substrate, and forming a gate stack on the SOI substrate;
b) conducting amorphous implantation to source/drain regions, wherein process temperature of the amorphous implantation to the source region is higher than process temperature of the amorphous implantation to the drain region;
c) performing source/drain region doping; and
d) annealing to activate dopants and recrystallize the amorphous region of the source/drain regions.

2. The method according to claim 1, wherein:
in step b), the process temperature is higher than 50° C. in the amorphous implantation to the source region; and the process temperature is lower than −30° C. in the amorphous implantation to the drain region.

3. The method according to claim 1, wherein source/drain extension regions and sidewall spacers are also formed after the formation of the gate stack in step a).

4. The method according to claim 1, wherein in step b), the method further comprises covering the drain region before the amorphous implantation to the source region.

5. The method according to claim 1, wherein in step b), the method further comprises covering the source region before the amorphous implantation to the drain region.

6. The method according to claim 1, wherein in step d), for NMOS devices, the source/drain regions are n-type doped and the ions implanted are P or As; and for PMOS devices, the source/drain regions are p-type doped and the ions implanted are B or BF2.

7. The method according to claim 1, wherein the annealing temperature is higher than 900° C. in step d).

8. The method according to claim 1, wherein in step b), the order for amorphous implantation of the source region and the drain regions is exchanged.

9. The method according to claim 1, wherein in step b), the ion implanted by amorphous implantation is silicon or germanium and the implantation depth is 50˜70 nm.

10. The method according to 2, wherein in step b), the ion implanted by amorphous implantation is silicon or germanium and the implantation depth is 50˜70 nm.

11. The method according to 3, wherein in step b), the ion implanted by amorphous implantation is silicon or germanium and the implantation depth is 50˜70 nm.

12. The method according to 4, wherein in step b), the ion implanted by amorphous implantation is silicon or germanium and the implantation depth is 50˜70 nm.

13. The method according to 5, wherein in step b), the ion implanted by amorphous implantation is silicon or germanium and the implantation depth is 50˜70 nm.

14. The method according to 6, wherein in step b), the ion implanted by amorphous implantation is silicon or germanium and the implantation depth is 50˜70 nm.

15. The method according to 7, wherein in step b), the ion implanted by amorphous implantation is silicon or germanium and the implantation depth is 50˜70 nm.

16. The method according to 8, wherein in step b), the ion implanted by amorphous implantation is silicon or germanium and the implantation depth is 50˜70 nm.
